(19) United States
(12) Patent Application Publication
(10) Pub. No.: US 2006/0126395 A1
(43) Pub. Date: Jun. 15, 2006

(54) Non-volatile memory cell and operating method thereof

(76) Inventors: Shih-Hung Chen, Hsinchu (TW); Yi-Chou Chen, Hsinchu (TW)

Correspondence Address: J C PATENTS, INC., 4 VENTURE, SUITE 250, IRVINE, CA, 92618, US

(21) Appl. No.: 11/180,093

(22) Filed: Jul. 11, 2005

(30) Foreign Application Priority Data
Dec. 10, 2004 (TW) 93138334

(51) Int. Cl. G11C 16/04; G11C 11/34

(52) U.S. Cl. 365/185.24; 365/185.05

(57) ABSTRACT

A non-volatile memory cell is provided. The non-volatile memory cell includes of a threshold switch material thin film and a memory switch material thin film, and the phases of the memory switch material layer is capable of changing. In addition, the memory switch material layer serves as a memory unit; the threshold switch material serves as a steering unit. Furthermore, the steering unit will breakdown when a voltage larger than its threshold voltage is provided, and the phase restores to the original state when the voltage is off.

### CROSS-REFERENCE TO RELATED APPLICATION

This application claims the priority benefit of Taiwan application serial no. 93138334, filed on Dec. 10, 2004. All disclosure of the Taiwan application is incorporated herein by reference.

### BACKGROUND OF THE INVENTION

1. Field of the Invention

The present invention relates to a memory device and an operating method thereof. More particularly, the present invention relates to a non-volatile memory and an operating method thereof.

2. Description of Related Art

In general, a non-volatile memory is formed with a plurality of steering units and a plurality of memory units, wherein the steering units are, for example, metal oxide semiconductor (MOS) transistors, used in controlling the various memory units. Further, a chalcogenide compound, comprising the phase change characteristics (between amorphous and crystalline) after being heated, can serve as a memory unit.

Traditionally, a chalcogenide memory requires high operation current, in which a further shrinkage of the cell is limited by the MOS size. One approach to resolve the above-mentioned problem is to replace the MOS transistor with a bipolar junction transistor, which can withstand a high current. However, a bipolar junction transistor is not a main stream device in the integrated circuit industry. Another approach is to replace the original MOS transistor with a diode. However, a diode can not withstand a high current either. Therefore, the ability to further shrinking the cell is limited.

### SUMMARY OF THE INVENTION

Accordingly, one object of the present invention is to provide a non-volatile memory, wherein the dimension of the memory cell can be reduced to increase the integration of the device.

Another object of the present invention is to provide a method for operating the above-mentioned nonvolatile memory device to resolve the problem of limiting operation current in the prior art.

The present invention provides a non-volatile memory, wherein the non-volatile memory is formed with a threshold switch material thin film and a memory switch material thin film. The memory switch material thin film is a memory unit; and the switch material thin film is a steer unit. When a voltage applied to the memory unit is greater than the threshold voltage of the phase-changeable thin film, a phase change occurs. However, when the applied voltage is discontinued, the original phase is restored.

The above memory switch material thin film and threshold switch material thin film are formed with a material that includes a chalcogenide compound, which includes a GeSbTe (germanium-antimony-tellurium) alloy, an AgInSbTe (silver-indium-antimony-tellurium) alloy or an AlAsTe (aluminum-arsenic-tellurium) alloy.

Further, the above non-volatile memory cell further includes a first electrode layer and a second electrode layer, and the memory switch material and threshold switch material thin films are disposed between the first and the second electrode layers.

Further, the above non-volatile memory cell further includes a contact disposed between the memory switch material and threshold switch material thin films.

Besides, the above non-volatile memory cell can also include a barrier layer, disposed between the memory switch material and threshold switch material thin films, or between the memory switch material thin film and the electrode or memory switch material thin film and the contact, or between the threshold switch material thin film and the electrode, or threshold switch material thin film and the contact.

The present invention further provides a method for operating a non-volatile memory, wherein the non-volatile memory comprises a plurality of non-volatile memory cells, a plurality of bit lines and a plurality of word lines electrically connected with each other. The nonvolatile memory cell is formed by serially connecting a steering unit with a memory unit. The memory unit and the steering unit are formed with a phase-changeable material. The operating method of the present invention includes selecting a selected memory cell from the non-volatile memory cells, and selecting a selected bit line and a selected word line that correspond to the selected memory cell. A first voltage is then applied to the selected word line while the selected bit line is set at zero volt. Further, a second voltage and a third voltage are applied to the other bit line and word line, wherein the second voltage and the third voltage are less than the first voltage.

Further, the operating method of the above mentioned non-volatile memory is applicable for programming and reading the non-volatile memory.

The non-volatile memory of the present invention is constructed with two layers of the phase-changeable thin film. Moreover, these two thin film layers serve as a steering unit and a memory unit, respectively. The dimension of the non-volatile memory can be further reduced to increase the degree of integration. Moreover, the phase-changeable thin film that serves as the steering unit can endure a higher current compared to a conventional transistor. The current leakage problem can thus easily resolved.

The above is a brief description of some deficiencies in the prior art and advantages of the present invention. Other features, advantages and embodiments of the invention will be apparent to those skilled in the art from the following description, accompanying drawings and appended claims.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a schematic diagram illustrating the current-voltage relationship of a memory switch material thin film that comprises a memory characteristic.

FIG. 1B is a schematic diagram illustrating the current-voltage relationship of a threshold switch material thin film that comprises a steering characteristic.

FIG. 2 is schematic diagram illustrating a 3-dimensional view of a non-volatile memory according to one embodiment of the present invention.

FIG. 3 is a schematic diagram illustrating a 3-dimensional cross-sectional view of a non-volatile memory according to another embodiment of the present invention.

FIG. 4 is a schematic diagram illustrating a memory array according to one embodiment of the present invention.

FIG. 5 is a schematic diagram illustrating a single memory cell in FIG. 4.

FIG. 6 is a schematic diagram illustrating an operation of a memory array of the present invention using a floating method.

FIG. 7 is a schematic diagram illustrating an operation of a memory array of the present invention using a bias method.

FIG. 8 is a schematic diagram illustrating an operation of a memory array of the present invention using a V/2 bias method.

FIG. 9 is a schematic diagram illustrating an operation of a memory array of the present invention using a V/3 bias method.

### DESCRIPTION OF THE EMBODIMENTS

The phase-changeable thin film of present invention now will be described more fully hereinafter with reference to a chalcogenide compound, in which a phase change (between an amorphous state to a crystalline state) is generated after being heated. This invention may, however, be embodied in other materials that comprise the similar characteristics and should not be construed as limited to the embodiments set forth herein.

Since the chalcogenide material formed with different composition ratios comprises different ovonic switch characteristics, the present invention relies on the different ovonic switch characteristics to select the appropriate the chalcogenide thin film as the memory unit or the steering unit.

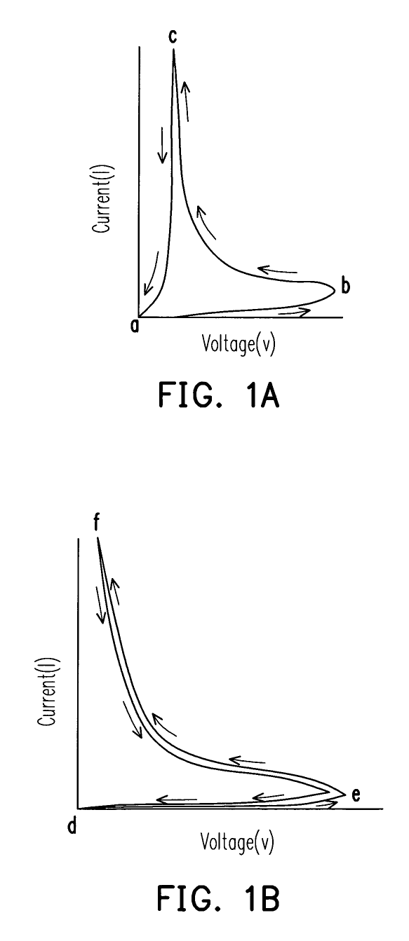

As embodied hereinafter, the chalcogenide material serving as a memory unit displays a voltage-current relationship curve as shown in FIG. 1A. When a voltage smaller than the threshold voltage (the corresponding voltage at “b” on the curve) of this chalcogenide material is applied, the relationship between current and voltage is characterized by the curve a-b. When a voltage larger than the threshold voltage of this chalcogenide material, the amorphous phase of the chalcogenide material changes to a crystalline phase. The resistance of the material drops accordingly. At this point, the voltage-current relationship curve is as depicted in curve b-c and the chalcogenide material is considered to be [ON]. When the above voltage (greater than the threshold voltage of the chalcogenide compound) is off, the current will return from point “c” to zero along the curve c-a. The chalcogenide material is still in a crystalline phase, and the [ON] state persists. Therefore, a chalcogenide material with a voltage-current relationship curve as shown in FIG. 1 can use the crystalline state and the amorphous state to represent [0] or [1], and thus can use as a memory unit.

Referring to FIG. 1B, FIG. 1B is a voltage-current relationship curve of a chalcogenide material serving as a steering unit. As the voltage applied to the chalcogenide material is smaller than the threshold voltage (the corresponding voltage at point “e” on the curve), the relationship between current and voltage is characterized by the curve d-e. When the voltage applied to the chalocgenide material is greater than the threshold voltage, the chalcogenide material will breakdown down, and the resistance of the material is also lower. At this point, the voltage-current relationship of the chalcogenide material is as depicted in curve e-f, and the material is considered at an [ON] state. When the above voltage (greater than the threshold voltage of the chalcogenide material) is off, the current will return from point ‘f’ to zero along the curve f-e-d. Further, the chalocgenide material also returns to the original amorphous phase, which can be considered as an [Off] state. Accordingly, the chalocgenide material displaying the voltage-current relationship curve as in FIG. 1B is similar to a diode, which can be used as a steering unit.

The operation of a chalocgenide memory is further described in Table 1.

TABLE 1

| | | | | Second Pulse |
|---|---|---|---|---|
| | | | First Pulse | (Pulse |
| | | | (Pulse | width = 100 ns, |
| | | | width = 10 ns, | temperature is |
| | Time | | temperature | between |
| | Required | | is greater than | melting and |
| | for | | melting | crystallization |
| Material | Crystallization | Initial Phase | temperature) | temperature) |
| A | 10 μs | Amorphous | Amorphous | Amorphous |
| B | 50 ns | Amorphous | Amorphous | Crystalline |
| | | | | (resistance |
| | | | | lower) |

As shown in Table 1, the time required for crystallization of material A is longer. Therefore, even using the second pulse with a greater pulse width for heating, material A will return to the original amorphous phase. Accordingly, material A is more appropriate as a steering unit. Since the time required for crystallization of material B is shorter, material B will start crystallizing when it is being heated with the second pulse with a greater pulse width. Further, even when the second pulse fades, the crystalline phase remains. Accordingly, material B is appropriate as a memory unit.

In one embodiment of the invention, the chalcogenide material is a GeSbTe alloy, an AgInSbTe alloy or an AlAsTe alloy, for example. Further, different alloy ratios provide different ovonic switch characteristics. For example, the voltage-current relationship curve of the Al₂₀As₁₅Te₇₅ alloy is as shown in FIG. 1A, and thus can be used as a memory unit. The AlAsTe alloy with the other alloy ratios, such as, Al₂₀As₁₅Te₆₅, Al₂₀As₁₅Te₅₅, Al₂₀As₃₅Te₄₅, displaying the voltage-current relationship curve as shown in FIG. 1B, can serve as a steering unit.

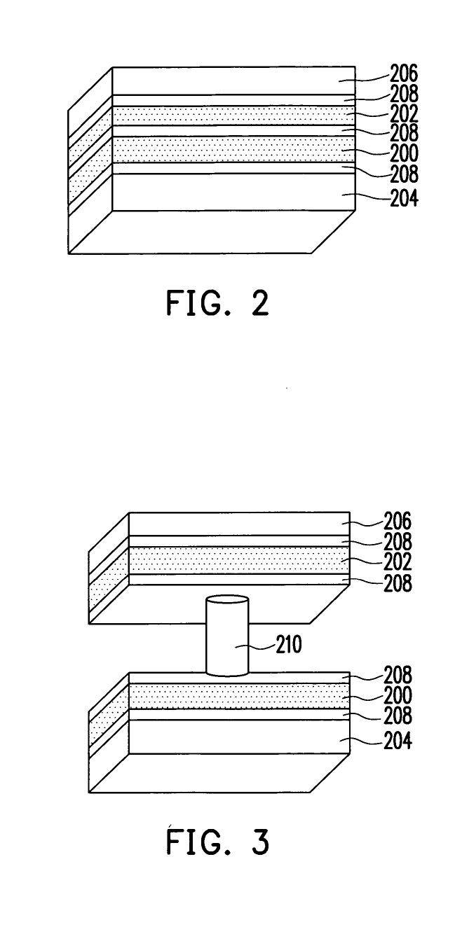

FIG. 2 is a schematic diagram illustrating a 3-dimensional view of a non-volatile memory according to one embodiment of the present invention.

Referring to FIG. 2, the non-volatile memory cell of the present invention is constructed with two chalcogenide thin films 200, 202, wherein the chalcogenide thin film 202 is diposed above the chalcogenide thin film 200. In one embodiment, the chalcogenide thin film 200, displays the current-voltage relationship as shown in the current-voltage relationship curve in FIG. 1A, and is used as a memory unit. The chalcogenide thin film 202 displays the current-voltage relationship as shown in the current-voltage relationship curve in FIG. 1B, and thus is used as a steering unit. In another embodiment, the positions of these chalcogenide thin films can be exchanged. In other words, the chalcogenide thin film 200 can be a steering unit, while the chalcogenide thin film 202 can be a memory unit.

In one embodiment of the invention, the non-volatile memory cell further includes, besides the above chalcogenide thin films 200 & 202, an upper electrode 204 and a lower electrode 206, wherein the chalcogenide thin films 200 & 202 are disposed between the upper and lower electrodes 204 & 206.

In one embodiment of the invention, the non-volatile memory cell further includes barrier layers 208, disposed between the two chalcogenide thin films 200, 202, the chalcogenide thin film 202 and the electrode 204 or the chalcogenide thin film 202 and the electrode 206. A material used in forming the barrier layer 208 is a conductive material, for example.

In another embodiment, the non-volatile memory cell of the invention further includes a contact 210, disposed between the two chalcogenide thin films 200, 202 (as shown in FIG. 3). More specifically, the barrier layer 208 is disposed between the contact 210 and the chalcogenide thin films 200, 202. A material used in forming the contact 210 is a conductive material, for example.

The non-volatile memory cell of this invention is formed with two phase-changeable thin films (for example, chalcogenide thin film), wherein these two phase-changeable thin films serve respectively a steering unit and a memory unit. The size of the non-volatile memory cell can be reduced to increase the integration of the device.

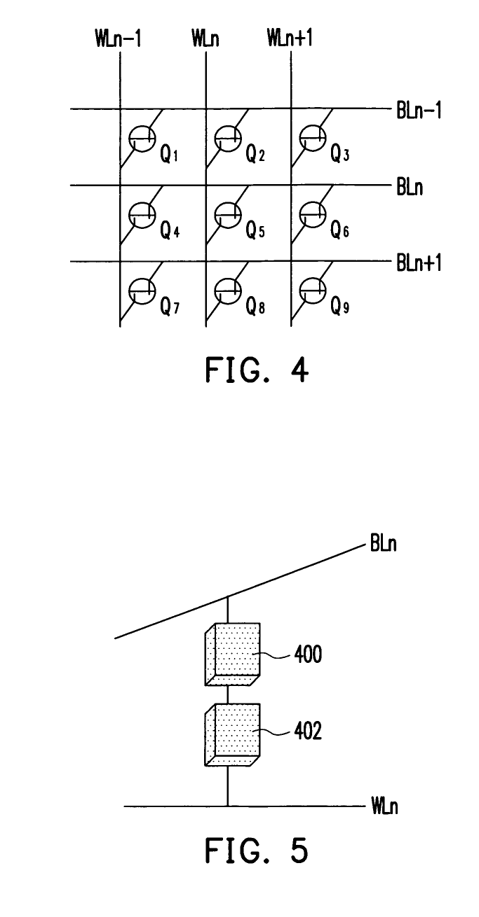

The operating method for the above non-volatile memory cell now will be described more fully hereinafter. A memory array formed with a plurality of memory cells Q₁˜Q₉, a plurality of bit lines BLₙ₋₁˜BLₙ₊₁ and a plurality of word lines WLₙ₋₁˜WLₙ₊₁ electrically connecting to each other is shown in FIG. 4. Further, each of the memory cells Q₁˜Q₉ is formed by serially connecting a steering unit 400 and a memory unit 402 (as shown in FIG. 5), wherein the steering unit 400 and the memory unit 402 are constructed with phase-changeable materials. More specifically, the cross-sectional structure of the memory cells is not limited to the structure disclosed in FIG. 4. As long as the steering unit 400 and the memory unit 402 are electrically connected in series and are formed with phase-changeable materials, the following operating method can be applied.

In the present invention, the operating method applicable for the memory cells Q₁˜Q₉ includes, but not limited to, the floating method and the bias method. These two operating methods are applicable for programming and reading the memory cells Q₁˜Q₉.

Floating Method

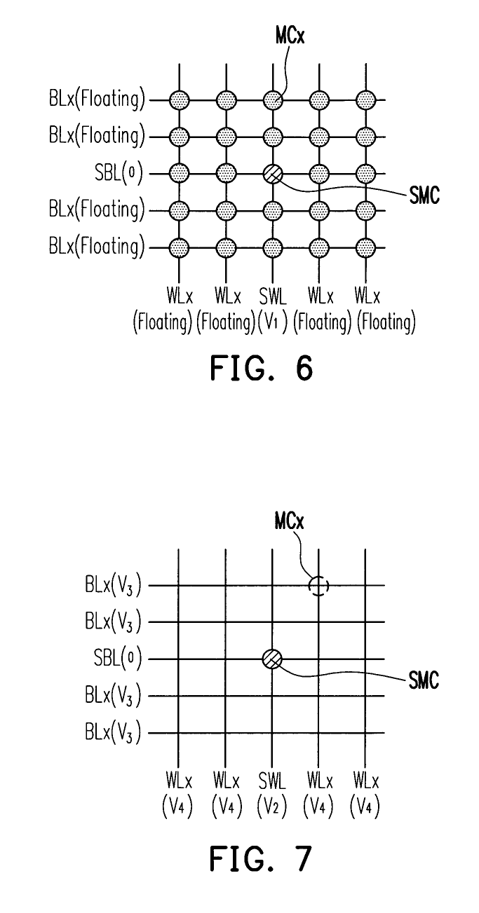

Referring to FIG. 6, FIG. 6 is a schematic diagram of a memory array. The operating method of this invention includes choosing selected memory cells SMC among the plurality of memory cells, and choosing, among the plurality of the bit lines and the plurality of the word lines, selected bit lines and selective word lines corresponding to the selected memory cells. Other non-selected memory cells, bit lines and word lines are designated as BCₓ, BLₓ and WLₓ.

Thereafter, an voltage V₁ is applied to the selected word lines SWL, while the selected bit lines SBL are set at zero volt. Other non-selected bit lines BLₓ and the non-selected word lines WLₓ are set at floating. At this point, the selected memory cells SMC are set at a voltage of V₁ and the non-selected memory cells MCₓ disposed at the non-selected bit lines BLₓ and the non-selected word lines WLₓ are only affected by the voltage between the range of −V₁ and V₁. The problem of a leakage current is thus improved.

The following Table 2 will now be used to describe the voltages required for applying to the various bit lines and word lines for the programming of the selected memory cells SMC using the floating method.

TABLE 2

| | Program [1] | Program [0] |
|---|---|---|
| Selected Bit Line SBL | 0 | 0 |
| Non-selected Bit Line BLx | Floating | Floating |
| Selected Word Line SWL | Vpl | Vph |
| Non-selected Word Line WLx | Floating | Floating |

Vpl: a lower programming voltage (V1)
Vph: a higher programming voltage (V1)

Bias Method

Referring to FIG. 7, FIG. 7 is a schematic diagram of a memory array. The operating method of the present invention includes choosing a selected memory cell from the plurality of the memory cells, and choosing, from the plurality of the bit lines and the plurality of the word lines, selected bit lines SBL and selected word lines SWL corresponding to the selected memory cells SMC. The non-selected memory cells, bit lines and word lines are designed as MCₓ, BLₓ and WLₓ, respectively.

A voltage V₂ is applied to the selected word lines SWL, while the selected bit lines SBL are set at zero volt. Further, the non-selected bit lines BLₓ and the word lines WLₓ are respectively applied with the voltage V₃ and the voltage V₄, wherein V₃ and V₄ are lower than V₂. The voltage applied to the selected memory cells SMC is V₂.

The following Table 3 will now be used to describe the voltages required for applying to the various bit lines and word lines for the programming of the selected memory cells SMC using the bias method.

TABLE 3

| | Program [1] | Program [0] |
|---|---|---|
| Selected Bit Line SBL | 0 | 0 |
| Non-selected Bit Line BLx | 0 ≦ V₃ ≦ Vpl | 0 ≦ V₃ ≦ Vph |
| Selected Word Line SWL | Vpl | Vph |
| Non-selected Word Line WLx | 0 ≦ V₄ ≦ Vpl | 0 ≦ V₄ ≦ Vph |

Vpl: a lower programming voltage (V₂)
Vph: a higher programming voltage (V₂)

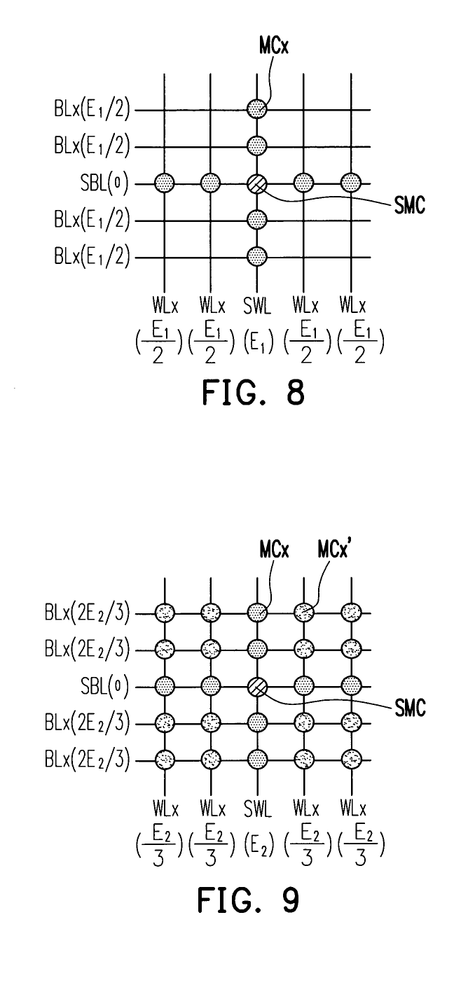

In one embodiment, the above bias method is a V/2 bias method, for example. Assuming the voltage V₂ is E₁volts, the voltage V₃ and the voltage V₄ are set as E₁/2 volts (as shown in FIG. 8). The voltage applied to the selected memory cells SMC is E₁ volts. Other non-selected memory cells MCₓ disposed at the selected bit lines and the selected word lines will only be affected by E₁/2 volts. The current leakage problem is thus effectively improved.

The following Table 4 will now be used to describe the voltages required for applying to the various bit lines and word lines for the programming of the selected memory cells SMC using the V/2 bias method.

TABLE 4

| | Program [1] | Program [0] |
|---|---|---|
| Selected Bit Line SBL | 0 | 0 |
| Non-selected Bit Line BLx | Vpl/2 | Vph/2 |
| Selected Word Line SWL | Vpl | Vph |
| Non-selected Word Line WLx | Vpl/2 | Vph/2 |

Vpl: a lower programming voltage (E₁)
Vph: a higher programming voltage (E₁)

In another embodiment, the above bias method is the V/3 biased method. Assuming the voltage V₂ is E₂ volts, while the voltage V₃ and the voltage V₄ are set as 2E₂/3 volts and E₂/3Vvolts (as shown in FIG. 9). When the voltage applied to the selected memory cells SMC is E₂, the other non-selected memory cells MCₓ disposed at the selected bit lines SBL and the selected word lines SWL will only be affected by E₂/3 volts. Further, other non-selected memory cells MCₓ that are disposed at the non-selected bit lines BLₓ and the non-selected word lines WLₓ will only be affected by −E₂/3 volts. As a result, the current leakage problem can be effectively improved.

The following Table 5 will now be used to describe the voltages required for applying to the various bit lines and word lines for the programming of the selective memory cells SMC using the V/3 bias method.

TABLE 5

| | Program [1] | Program [0] |
|---|---|---|
| Selected Bit Line SBL | 0 | 0 |
| Non-selected Bit Line BLx | 2Vpl/3 | 2Vph/3 |
| Selected Word Line SWL | Vpl | Vph |
| Non-selected Word Line WLx | Vpl/3 | Vph/3 |

Vpl: a lower programming voltage (E₂)
Vph: a higher programming voltage (E₂)

Since the thin film serving as the steering unit of the present invention can withstand a high current even the device dimension is reduced, the cell shrink ability is extend.

Accordingly, the non-volatile memory of the present invention is constructed with two layers of thin film, wherein these thin film layers serve as a steering unit and a memory unit. Therefore, the dimension of the non-volatile memory can be reduced to increase the integration of the device.

Since the two thin film layers can serve as a steering unit and a memory unit, the fabrication process is much simpler, compared to that of integrating a transistor type of steering unit and a memory unit.

Further, the non-volatile flash memory device of the present invention can be integrated in a logic circuit to form the system on a chip (SOC). The non-volatile memory of this invention can also provide a faster programming and reading speed. In addition, the programming voltage (less than 5V) of the non-volatile memory of this invention is less than the programming voltage (˜10V) of a flash memory.

The foregoing description of the preferred embodiment of the present invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

What is claimed is:

1. A non-volatile memory, comprising:
a threshold switch material thin film; and
a memory switch material thin film, disposed on the memory switch material serves as a memory unit, while the threshold switch material thin film serves as a steering unit, wherein when a voltage is applied to the threshold switch material thin film that serves as the steering unit is greater than a threshold voltage of the threshold switch material, an electric breakdown occurs, and when the voltage is off, an original phase is restored.

2. The memory of claim 1, wherein the threshold switch material thin film and the memory switch material thin film include a chalcogenide compound.

3. The memory of claim 2, wherein the chalcogenide compound includes a GeSbTe alloy, an AnInSbTe alloy or an AlAsTe alloy.

4. The memory of claim 1 further comprising a barrier layer, disposed between the threshold switch material thin film and the memory switch material thin film.

5. The memory of claim 1 further comprising a first electrode layer and a second electrode layer, wherein the threshold switch material thin film and the memory switch material thin film are disposed between the first and the second electrode layers.

6. The memory of claim 5 further comprising a first barrier layer disposed between the threshold switch material thin film and the first electrode and between the memory switch material thin film and the second electrode.

7. The memory of claim 5 further comprising a second barrier layer disposed between the threshold switch material thin film and the memory switch material thin film.

8. The memory of claim 6 further comprising a second barrier layer disposed between the threshold switch material thin film and the memory switch material thin film.

9. The memory of claim 1 further comprising a contact disposed between the threshold switch material thin film and the memory switch material thin film.

10. The memory of claim 9 further comprises a barrier layer, disposed between the contact and the threshold switch material thin film, and between the contact and the memory switch material thin film.

11. The memory of claim 9 further comprising a first electrode layer and a second electrode layer, and the threshold switch material thin film and the memory switch material thin film are disposed between the first electrode layer and the second electrode layer.

12. The memory of claim 11 further comprising a first barrier layer, disposed between the threshold switch material thin film and the first electrode layer, and between the memory switch material thin film and the second electrode layer.

13. The memory of claim 11 further comprising a second barrier layer disposed between the contact and the threshold switch material thin film, and between the contact and the memory switch material thin film.

14. The memory of claim 12 further comprising a second barrier layer disposed between the contact and the threshold switch material thin film, and between the contact and the memory switch material thin film.

15. A method for operating a non-volatile memory, the non-volatile memory comprising a plurality of non-volatile memory cells, a plurality of bit lines and a plurality of word lines electrically connected to each other, and each non-volatile memory cell comprises a steering unit and a memory unit serially connected together, wherein a material used in forming the steering unit and the memory unit comprises a phase-changeable material, the method comprising:
choosing a selected non-volatile memory cell from the non-volatile memory cells and choosing a selected bit line and a selected word layer corresponding to the selected non-volatile memory cell from the bit lines and the word lines; and
applying a voltage to the selected word line and setting the selected bit line at zero volt, while setting non-selected word lines and non-selected bit lines at floating.

16. The method of claim 15 is applicable for a programming or a reading of the non-volatile memory.

17. An operating method for a non-volatile memory, wherein the non-volatile memory is constructed with a plurality of non-volatile memory cells, a plurality of bit lines and a plurality of word lines electrically connected with each other, wherein the non-volatile memory cells are formed by serially connecting a steering unit and a memory unit, and the steering unit and the memory unit are formed with a phase-changeable material, the operating method comprising:
choosing a selected non-volatile memory cell from the non-volatile memory cells and choosing a selected bit line and a selected word line that correspond to the selected non-volatile memory cell from the bit lines and the word lines; and
applying a first voltage to the selected word line and setting the bit line at zero volt, and applying a second voltage and a third voltage to the bit line and the word line, respectively, wherein the second voltage and the third voltage are lower than the first voltage.

18. The method of claim 17, wherein the first voltage is V volt, and the second voltage and the third voltage are 1/2V volt.

19. The method of claim 17, wherein the first voltage is V volt, and the second voltage is 2/3V volt and the third voltage is 1/3V volt.

20. The method of claim 17 is applicable for a programming and a reading of the non-volatile memory.
